(19) United States
(12) Patent Application Publication
(10) Pub. No.: US 2026/0292974 A1
(43) Pub. Date: Sep. 24, 2026

(54) Laser Unit for a Rotating Laser and Rotating Laser having the Laser Unit

(71) Applicant: Robert Bosch GmbH, Stuttgart (DE)

(72) Inventors: Markus Hahl, Korntal-Muenchingen (DE); Ben William Carabelli, Leinfelden-Echterdingen (DE); Tobias Roehm, Wildberg-Sulz (DE)

(21) Appl. No.: 19/570,874

(22) Filed: Mar. 18, 2026

(30) Foreign Application Priority Data
Mar. 20, 2025 (DE) 10 2025 110 734.3

(51) Int. Cl. H05K 1/02; G01C 15/00; H01S 5/023

(52) U.S. Cl. CPC H05K 1/0277; G01C 15/004; H01S 5/023; H05K 2201/09027; H05K 2201/10121

(57) ABSTRACT

A laser unit for a rotating laser, has a laser module housing, in which a laser diode for generating a laser beam, and a collimation lens for collimating the laser beam, are arranged. The laser diode is arranged on a flexible and foldable printed circuit board.

This application claims priority under 35 U.S.C. § 119 to patent application no. DE 10 2025 110 734.3, filed on Mar. 20, 2025 in Germany, the disclosure of which is incorporated herein by reference in its entirety.

### BACKGROUND

The present disclosure relates to a laser unit for a rotating laser, having a laser module housing, in which a laser diode for generating a laser beam, and a collimation lens for collimating the laser beam, are arranged.

A rotating laser having such a laser unit is known from the prior art. The laser unit comprises a laser module housing, in which a laser diode for generating a laser beam, and a collimation lens for collimating the laser beam, are arranged.

### SUMMARY

The disclosure relates to a laser unit for a rotating laser, having a laser module housing, in which a laser diode for generating a laser beam, and a collimation lens for collimating the laser beam, are arranged. The laser diode is arranged on a flexible and foldable printed circuit board.

The disclosure thus enables the provision of a laser unit, in which a simple and stable arrangement of the laser diode in the laser module housing may be achieved by the flexible and foldable printed circuit board.

Preferably, the flexible and foldable printed circuit board comprises a first printed circuit board section, and a second printed circuit board section arranged perpendicular or parallel to the first printed circuit board section.

Thus, a printed circuit board prepared for receiving different elements may be provided.

Preferably, the first printed circuit board section is provided for arranging the laser diode, and the second printed circuit board section is provided for arranging a photodiode.

Thus, the flexible and foldable printed circuit board may be used and straightforwardly for arranging the laser diode and the photodiode.

Preferably, a laser diode holder for arranging the laser diode in the laser module housing is provided, wherein the laser diode holder is arranged in an inner receptacle of the laser module housing.

Thus, an arrangement of the laser diode in the laser module housing may be achieved in a simple manner.

Preferably, the laser diode holder is arranged so as to be displaceable along a longitudinal extent of the laser module housing in the inner receptacle of the laser module housing.

Thus, an exact and precise arrangement of the laser diode holder in the laser module housing may be achieved.

Preferably, the flexible and foldable printed circuit board is arranged on the laser diode holder.

Thus, a secure and reliable arrangement of the flexible and foldable printed circuit board in the laser module housing may be achieved.

Preferably, a photodiode is provided, which is arranged in a photodiode holder, and the photodiode holder is arranged on the laser diode holder.

Thus, a simple and robust arrangement of the photodiode holder in the laser module housing may be achieved.

Preferably, a third printed circuit board section arranged parallel to the first printed circuit board section is provided.

Thus, an alternative embodiment of the flexible and foldable printed circuit board for receiving further elements may be achieved.

Preferably, the first printed circuit board section or the third printed circuit board section is connected to a contacting element via a flexible connecting section.

Thus, contacting with a power supply and/or an electronic unit may be achieved easily and straightforwardly.

According to one embodiment, a receptacle is formed between the first and third printed circuit board sections, in which a spacer element is arranged.

Thus, a secure and reliable arrangement of the first printed circuit board section relative to the third printed circuit board section may be achieved.

Preferably, the first printed circuit board section is fixed to the laser diode holder by way of a material-bonded connection, the second printed circuit board section is fixed to the photodiode holder by way of a material-bonded connection, and/or the spacer element is fixed to the first printed circuit board section and/or the third printed circuit board section by way of a material-bonded connection.

Thus, a connection between the first printed circuit board section and the laser diode holder, the second printed circuit board section and the photodiode holder, and/or the spacer element and the first and/or third printed circuit board sections may be achieved in a simple manner.

Preferably, a shielding element is assigned to the flexible and foldable printed circuit board.

Thus, the electromagnetic compatibility of the laser unit may be improved simply and reliably.

Preferably, the flexible and foldable printed circuit board comprises a receiving region, which is delimited by lateral webs, and the shielding element comprises an inner receptacle for arrangement in the receiving region of the flexible and foldable printed circuit board.

Thus, a secure and robust arrangement of the shielding element in the laser module housing may be achieved.

Preferably, the shielding element is fixed to the flexible and foldable printed circuit board by way of a material-bonded connection, a latching connection, and/or a press connection.

Thus, a fixation of the shielding element may be achieved simply and reliably.

Furthermore, the present disclosure relates to a rotating laser having the described laser unit.

The disclosure thus enables the provision of a rotating laser having a laser unit, in which a simple and secure arrangement of the laser diode in the laser module housing may be achieved by the flexible and foldable printed circuit board.

### BRIEF DESCRIPTION OF THE DRAWINGS

The disclosure is explained in greater detail in the following description on the basis of exemplary embodiments illustrated in the drawings. It shows:

FIG. 1 a perspective view of a rotating laser according to the disclosure having a laser unit,

FIG. 2 a schematic view of the laser unit of FIG. 1,

FIG. 3 a schematic view of a printed circuit board assigned to the laser unit of FIG. 1 and FIG. 2,

FIG. 4 a schematic view of a first circuit assigned to the laser unit of FIG. 1,

FIG. 5 a schematic view of an alternative embodiment of the laser unit of FIG. 1,

FIG. 6 a perspective exploded view of a further embodiment of the laser unit of FIG. 1,

FIG. 7 a sectional view of the laser unit of FIG. 6,

FIG. 8 a schematic view of a second circuit assigned to the laser unit of FIG. 1,

FIG. 9 a perspective view of a printed circuit board assigned to the laser unit of FIG. 6 and FIG. 7 having a laser diode and a photodiode,

FIG. 10 a view of the printed circuit board having the laser diode and the photodiode of FIG. 9, viewed in the direction of an arrow 901 of FIG. 9,

FIG. 11 a schematic view of an alternative embodiment of the laser unit of FIG. 1,

FIG. 12 a perspective view of an alternative printed circuit board assigned to the laser unit of FIG. 6 and FIG. 7 having a laser diode and a photodiode,

FIG. 13 a plan view of a first side of the printed circuit board of FIG. 12,

FIG. 14 a plan view of a second side of the printed circuit board of FIG. 12 and FIG. 13,

FIG. 15 a perspective view of the printed circuit board of FIG. 12 to FIG. 14 in the installed state having fixing elements,

FIG. 16 a perspective view of the laser unit of FIG. 6 and FIG. 7 having the printed circuit board of FIG. 12 to FIG. 15,

FIG. 17 a perspective view of the laser unit of FIG. 16 having a shielding element arranged on the printed circuit board,

FIG. 18 a perspective view of the laser unit of FIG. 17 having the printed circuit board, and a perspective view of the shielding element, and

FIG. 19 a sectional view of the laser unit of FIG. 18.

### DETAILED DESCRIPTION

In the figures, elements having the same or comparable function are provided with identical reference signs and are described in greater detail only once.

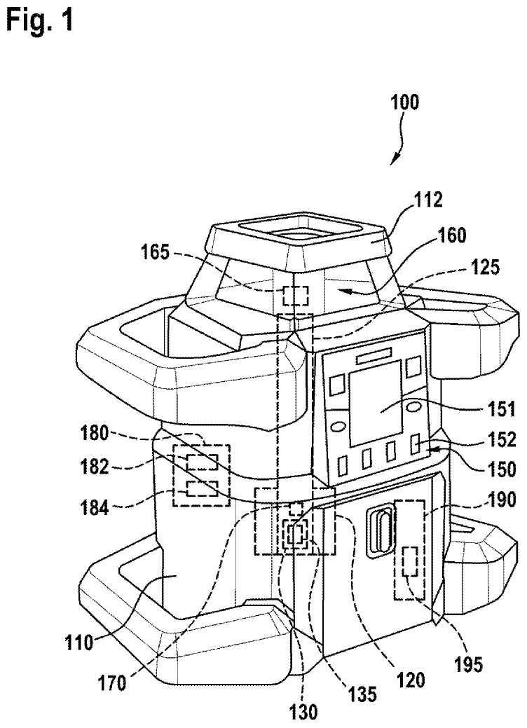

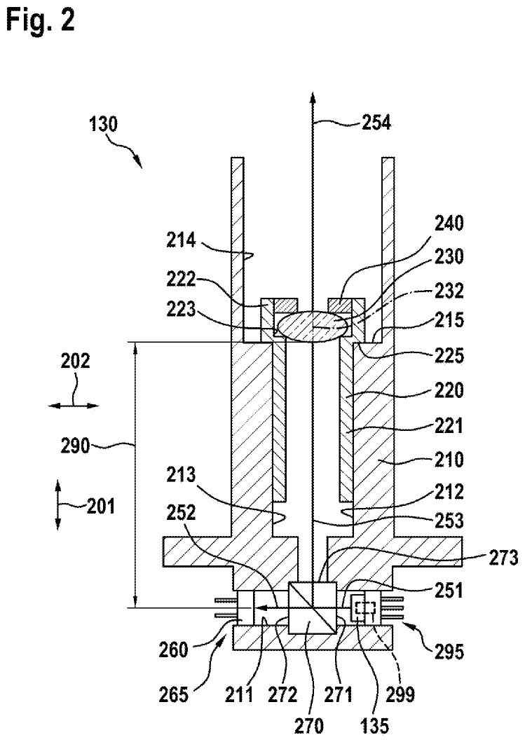

FIG. 1 shows a rotating laser 100, by way of example, having a laser housing 110, in which a laser unit 130 having a laser diode 135 for generating a laser beam (251 in FIG. 2) is arranged. In the context of the present disclosure, a “rotating laser” may also be understood as meaning a construction laser or a leveling laser. Furthermore, a drive unit 120 for rotatably driving a drive shaft 125 is arranged, by way of example, in the laser housing 110.

The laser unit 130 is arranged on the drive shaft 125 such that, by rotation of the drive shaft 125, the laser beam (251 in FIG. 2) generated by the laser unit 130 rotates in an assigned plane. For this purpose, a rotating head 160 having a beam deflector 165 is preferably assigned to the drive shaft 125. The beam deflector 165 is preferably configured to deflect the laser beam (254 in FIG. 2), whereby the laser beam (254 in FIG. 2) projects the assigned plane. Alternatively, the beam deflector 165 is configured as a beam splitter, whereby, in addition to the projected plane, a laser beam perpendicular to the laser plane is emitted along the laser axis (254 in FIG. 2). Depending on the configuration of the rotary laser 100, the projected plane may extend horizontally, vertically, or, for example, with a defined inclination angle relative to the ground surface. Preferably, the drive unit 120 is configured as an electric motor.

Furthermore, an electronics unit 190 having a control and monitoring device 195 is preferably arranged in the laser housing 110. The control and monitoring device 195 is preferably configured to control laser power of the laser unit 130 as a function of an operating mode. Herein, a rotational speed of the drive shaft 125 of the drive unit 120 is controlled or regulated. For this purpose, a determination unit 170 is preferably assigned to the drive shaft 125.

According to one embodiment, a protective cage 112 assigned to the rotation head 160 is assigned to the laser housing 110 for protection against striking of the rotating head 160.

An operating unit 150 having a display 151 and/or an input unit 152 is preferably assigned to the electronics unit 190. The operating unit 150 is preferably connected to the electronics unit 190, in particular, to the control and monitoring device 195, in terms of control engineering or regulation engineering. The input unit 152 preferably comprises at least one keypad. In a minimized embodiment, the input unit 152 comprises merely an on/off switch, in particular, an on/off pushbutton. Alternatively, the input unit 152 comprises a rotating control, a touchscreen, a slider, a remote control, or the like. A rotational speed for the drive shaft 125 may, for example, be input by a user via the input unit 152. Alternatively, the rotational speed of the laser unit 130 is automatically controllable in one operating mode.

Preferably, the rotating laser 100 comprises a leveling unit 180. The leveling unit 180 preferably comprises at least one inclination sensor 184, which is configured to determine an inclination of the rotating head 160, in particular, of the beam deflector 165, and/or of the laser unit 130 relative to a predefined direction, preferably a horizontal direction, or relative to the vertical. Furthermore, the leveling unit 180 preferably comprises at least one inclination adjustment motor 182, which is configured to align the rotating head 160, in particular, the beam deflector 165, and/or the laser unit 130 relative to the vertical as a function of a position determined by way of the at least one inclination sensor 184, preferably an inclination of the laser unit 130 and/or of the rotating head 160.

FIG. 2 shows an exemplary embodiment of the laser unit 130 of the rotating laser 100 of FIG. 1. A laser module housing 210 is assigned to the laser unit 130, in which the laser diode 135 for generating a laser beam 251, and a collimation lens 230 for collimating the laser beam 251, are arranged. A monitor diode 299 is assigned to the laser diode 135. The monitor diode 299 is configured for measuring a laser power assigned to the laser diode 135. According to one embodiment, the monitor diode 299 is a monitor diode integrated into the laser diode 135. Such a laser diode 135 having an integrated monitor diode 299 is sufficiently known from the prior art, for which reason a more detailed description is dispensed with here for the sake of brevity of the description.

According to the disclosure, the laser unit 130 comprises a photodiode 260, which is provided for a measurement of the laser power independent of the monitor diode 299.

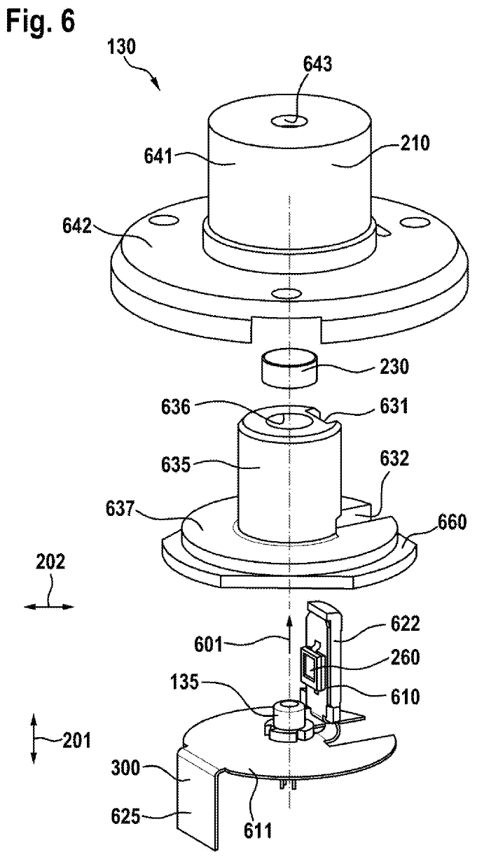

Preferably, a laser diode holder 295 (660 in FIG. 6) is assigned to the laser diode 135, a photodiode holder 265 (622 in FIG. 6) is assigned to the photodiode 260, and/or a collimation-lens holder 220 is assigned to the collimation lens 230. The collimation-lens holder 220 is arranged in an inner receptacle 212 of the laser module housing 210. The inner receptacle 212 is aligned along a longitudinal extent 201 of the preferably cylindrical laser module housing 210. Furthermore, the inner receptacle 212 is preferably arranged collinearly with an optical axis 232 of the collimation lens 230.

Preferably, a spacing 290 between the laser diode 135 and the collimation lens 230 is variable. For this purpose, the collimation-lens holder 220 is preferably arranged so as to be displaceable along the longitudinal extent 201 of the laser module housing 210 in the inner receptacle 212. Preferably, an aperture 240 is assigned to the collimation lens 230.

By way of example, the inner receptacle 212 comprises a lower receiving region 213, which widens via a bottom surface 215 into an upper receiving region 214. A lower section 221 of the collimation-lens holder 220 is arranged, by way of example, in the lower receiving region 213 of the inner receptacle 212, and an upper section 222 of the collimation-lens holder 220 is preferably arranged in the upper receiving region 214 of the inner receptacle 212. Here, an underside 225 of the upper section 222 of the collimation-lens holder 220 is arranged on the bottom surface 215 of the upper receiving region 214. The upper section 222 of the collimation-lens holder 220 comprises a lens receptacle 223 by way of example, in which the collimation lens 230 is arranged.

The collimation lens 230 comprises the optical axis 232. Along the optical axis 232, the laser beam 251 is collimated. The optical axis 232 is preferably arranged parallel to the longitudinal extent 201 of the laser module housing 210 within predefined tolerances. In the context of the present disclosure, an optical axis 232 is to be understood as a straight line through a center, in particular, a center of curvature of an optical device, here the lens or the collimation lens 230.

According to FIG. 2, the laser unit 130 comprises a beam splitter 270, which splits the laser beam 251 emanating from the laser diode 135 into preferably two outgoing laser beams 252, 253. For this purpose, the laser diode 135 is arranged on an incoming side 271 of the beam splitter 270. The photodiode 260 is preferably arranged on an outgoing side 272 of the beam splitter 270. Preferably, the collimation lens 230 is arranged on a further outgoing side 273 of the beam splitter 270.

The laser module housing 210 preferably comprises a receptacle 211, which forms the laser diode holder 295 for receiving the laser diode 135 and the photodiode holder 265 for receiving the photodiode 260. Preferably, the receptacle 211 is arranged along a transverse direction 202 of the laser module housing 210, which is arranged perpendicular to the longitudinal extent 201 of the laser module housing 210. Preferably, the beam splitter 270 is likewise arranged in the receptacle 211.

The laser diode 135 is arranged to the right of the beam splitter 270, and the photodiode 260 is arranged to the left of the beam splitter 270. Thus, the laser diode 135 and the photodiode 260 are arranged offset by 180° relative to one another, or opposite one another, on the beam splitter 270. Here, the laser diode 135 may also be arranged to the left of the beam splitter 270, and the photodiode 260 may be arranged to the right of the beam splitter 270. Alternatively, the laser diode 135 and the photodiode 260 may also be arranged at another angle relative to one another, for example, offset by 90° relative to one another.

The laser beam 251 is split into an outgoing laser beam 252, which is guided to the photodiode 260, and into an outgoing laser beam 253, which is guided to the collimation lens 230. The laser beam 253 is collimated by the collimation lens 230 into a collimated laser beam 254, or collected or bundled. Here, the rays of the laser beam 253 are aligned substantially parallel by the collimation lens 230, such that they spread only minimally in their propagation.

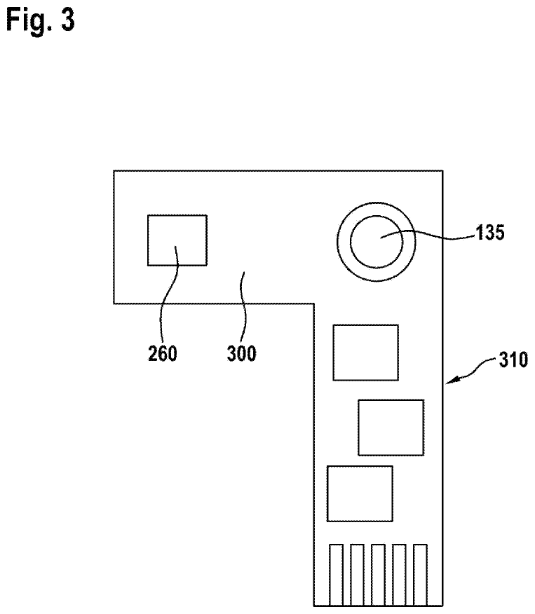

FIG. 3 shows a printed circuit board 300 assigned to the laser unit 130 of FIG. 1 and FIG. 2. The laser diode 135 of FIG. 1 and FIG. 2, and the photodiode 260 of FIG. 2, are preferably arranged on the printed circuit board 300. Preferably, circuit parts 310 are arranged on the printed circuit board 300. Three circuit parts 310 are arranged on the printed circuit board 300. However, it is noted that the printed circuit board 300 may comprise any number of circuit parts 310.

According to one embodiment, the printed circuit board 300 is formed as a flexible and foldable printed circuit board. Here, sections of the printed circuit board 300 may be arranged at predefined angles or parallel to one another.

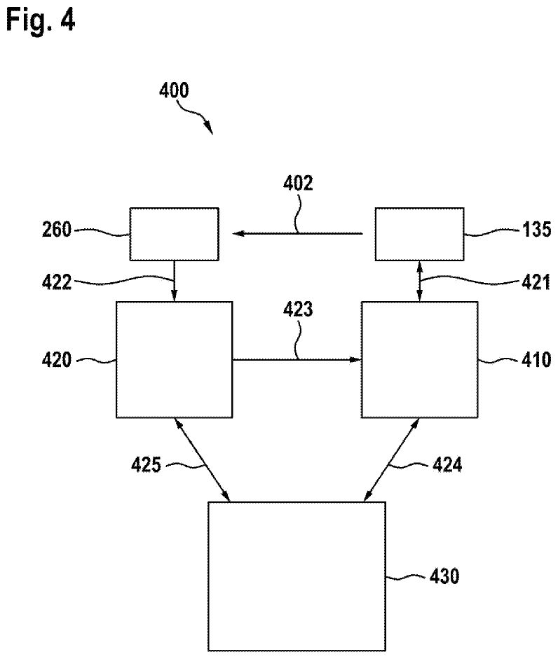

FIG. 4 shows a circuit 400 assigned to the laser unit 130 of FIG. 1. The circuit 400 preferably comprises at least one automatic power control circuit 410 assigned to the laser diode 135, and a protection circuit 420 assigned to a corresponding photodiode, for example the photodiode 260 of FIG. 2.

The laser diode 135 is connected to the automatic power control circuit 410 via a connection 421. The automatic power control circuit 410 is preferably configured for automatic control of a laser power of the laser diode 135 based on a measurement of the laser power by the monitor diode assigned to the laser diode 135, for example the monitor diode 299 of FIG. 2. Preferably, the connection 421 is bidirectional. Such an automatic power control circuit 410 is sufficiently known from the prior art and is therefore not described in greater detail. By way of example, the automatic power control circuit 410 is formed as an integral controller.

The laser beam emitted by the laser diode 135 is also guided to the photodiode 260, which is visualized by an arrow 402. In a further embodiment, the arrow 402 may also visualize or comprise scattered light. The photodiode 260 is preferably connected to the protection circuit 420 via a connection 422. Preferably, the connection 422 is unidirectional. Preferably, photocurrents determined by the photodiode 260 are transmitted to the protection circuit 420 via the connection 422.

As described above, the photodiode 260 is provided for a measurement of the laser power independent of the monitor diode 299 of FIG. 2. The protection circuit 420 is preferably connected to the automatic power control circuit 410 via a control line 423 and may deactivate the automatic power control circuit 410 via the control line 423 if the laser power measured by the photodiode 260 exceeds a predefined laser-power limit value.

Furthermore, further circuit parts 430 are preferably connected to the protection circuit 420 via a connection 425. Preferably, the further circuit parts 430 are connected to the automatic power control circuit 410 via a connection 424. The further circuit parts 430 comprise, for example, a current/voltage supply and/or a control unit, in particular, the electronic unit 190 of FIG. 1 of the rotating laser 100 of FIG. 1.

Preferably, the control of the laser power is based on a comparison of the laser power measured by the monitor diode 299 with a predefined laser-power setpoint value. The laser-power setpoint value is smaller than the laser-power limit value for the protection circuit 420. Both the laser-power setpoint value and the laser-power limit value are configured, for example, by a control circuit assigned to the circuit parts 430 and are preferably variable.

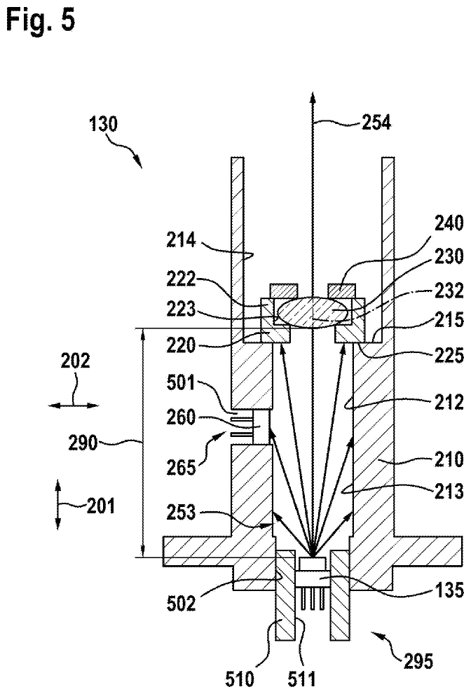

FIG. 5 shows an alternative embodiment of the laser unit 130 of FIG. 1 having the laser diode 135, the photodiode 260, and the collimation lens 230. Analogously to FIG. 2, the collimation-lens holder 220 is arranged in the upper receiving region 214 of the inner receptacle 212.

According to FIG. 5, the collimation-lens holder 220 comprises merely the upper section 222 of FIG. 2. Preferably, the underside 225 of the upper section 222 of the collimation-lens holder 220 rests on the bottom surface 215 of the upper receiving region 214. Here, the collimation-lens holder 220 is preferably arranged fixedly, that is to say non-displaceably, in the inner receptacle 212.

The laser diode holder 295 of the laser diode 135 comprises a base body 510 having an inner receptacle 511, in which the laser diode 135 is arranged. Preferably, the laser diode holder 295 is arranged in a receptacle 502 of the laser module housing 210. The receptacle 502 is preferably arranged collinearly with the optical axis 232 of the collimation lens 230. Here, a center point of the receptacle 502 is arranged on the optical axis 232. According to one embodiment, the laser diode holder 295 is arranged so as to be displaceable along the longitudinal extent 201 of the laser module housing 210 in the receptacle 502 for setting the spacing 290 between the laser diode 135 and the collimation lens 230.

Furthermore, the laser module housing 210 comprises, by way of example, a receptacle 501, which is arranged perpendicular to the receptacle 502 of the laser diode holder 295 within predefined tolerances. Here, the receptacle 501 is arranged perpendicular to the inner receptacle 212 of the laser module housing 210 within predefined tolerances. The receptacle 501 is formed in the lower section 213 of the inner receptacle 212 of the laser module housing 210. By way of example, the receptacle 501 forms the photodiode holder 265.

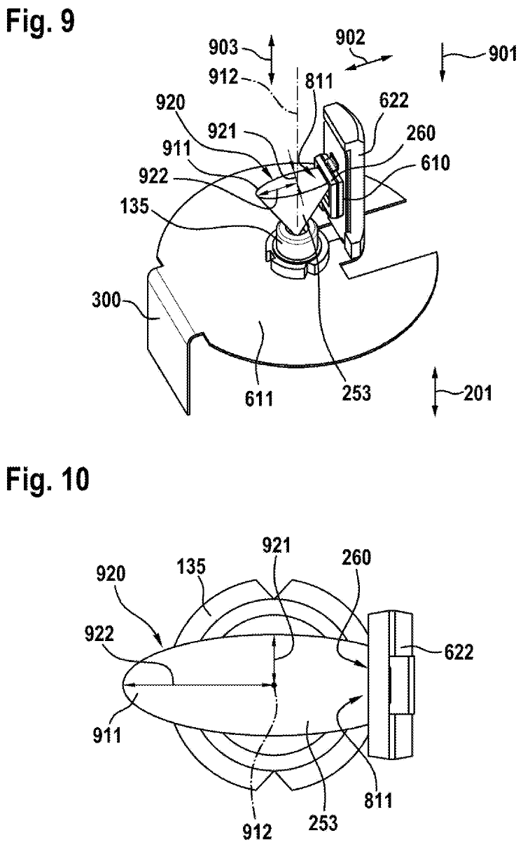

The receptacle 501, or the photodiode holder 265, is arranged spaced apart along the longitudinal extent 201 of the laser module housing 210 from the receptacle 502 of the laser diode holder 295. Here, the receptacle 501 is preferably arranged along a direction (922 in FIG. 9) of greatest divergence of a radiation characteristic (911 in FIG. 9) of the laser diode 135. A photocurrent assigned to the photodiode 260 preferably results from scattered light of the laser diode 135 due to the divergence of the uncollimated laser beam 253 of the laser diode 135.

The laser diode 135 and the photodiode 260 may be arranged on separate printed circuit boards. Here, the printed circuit boards are preferably formed as rigid or flexible printed circuit boards.

FIG. 6 shows a further embodiment of the laser unit 130 of FIG. 1, in which the laser diode 135 and the photodiode 260 are, by way of example, arranged on a common printed circuit board 300. Preferably, the printed circuit board 300 is formed as a flexible and foldable printed circuit board, as described above.

The printed circuit board 300 comprises at least a first printed circuit board section 611 and a second printed circuit board section 610. Preferably, the second printed circuit board section 610 is formed in the manner of a stamped-and-bent part. By way of example, the second printed circuit board section 610 is arranged approximately perpendicular to the first printed circuit board section 611. Preferably, the first printed circuit board section 611 forms a bottom section 611, and the second printed circuit board section 610 forms a wall section 610. The laser diode 135 is preferably arranged on the first printed circuit board section 611 or the bottom section 611, and the photodiode 260 is arranged on the second printed circuit board section 610 or the wall section 610.

Preferably, a contacting element 625 is assigned to the first printed circuit board section 611. The contacting element 625 serves for electrically contacting the printed circuit board 300 with at least one power source.

A photodiode holder 622 is preferably assigned to the photodiode 260, in particular, to the second printed circuit board section 610. A laser diode holder 660 is preferably assigned to the laser diode 135. The laser diode holder 660 is provided for arranging the laser diode 135 in the laser module housing 210. Here, the laser diode holder 660 is preferably arranged in an inner receptacle 643 of the laser module housing 210.

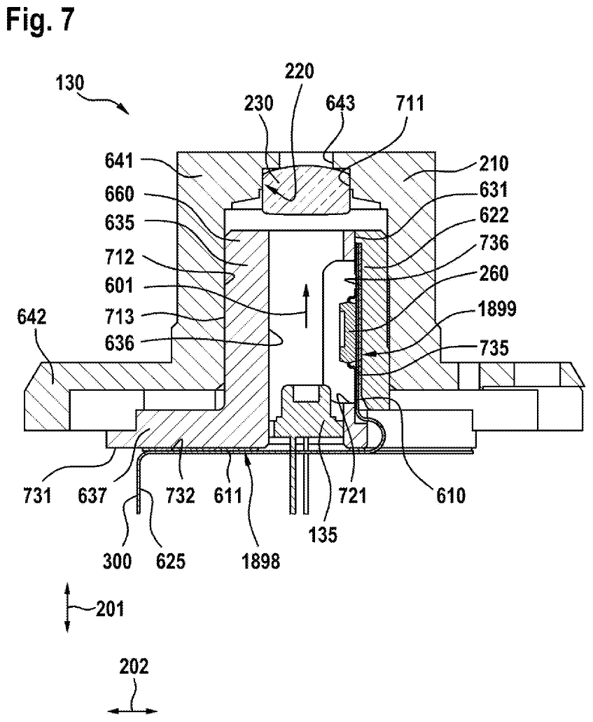

The laser diode holder 660 comprises a cylindrical base body 635 having an inner receptacle 636. Furthermore, the cylindrical base body 635 comprises, by way of example, at its outer circumference, a receptacle 631 having a recess (721 in FIG. 7) for arranging the photodiode 260 in the inner receptacle 636 of the laser diode holder 660. On its side facing away from the laser module housing 210, the laser diode holder 660 comprises a circumferential collar 637. The circumferential collar 637 comprises, by way of example, a recess 632 assigned to the receptacle 631, which is formed for arranging the photodiode holder 622 in the receptacle 631.

The laser module housing 210 preferably comprises a cylindrical base body 641 having the inner receptacle 643 for outputting the collimated laser beam 254 of FIG. 2 and FIG. 5 generated by the laser diode 135. Here, the inner receptacle 643 preferably assumes the function of the aperture 240 of FIG. 2. Preferably, the laser module housing 210 comprises a circumferential collar 642 facing the laser diode 135.

The flexible and foldable printed circuit board 300 is, by way of example, arranged on the laser diode holder 660. For this purpose, the first printed circuit board section 611 is preferably arranged on the circumferential collar 637 such that the laser diode 135 is arranged in the inner receptacle 636 of the laser diode holder 660. When the laser diode 135 is arranged in the inner receptacle 636, the second printed circuit board section 610 having the photodiode holder 622 is not arranged perpendicular to the first printed circuit board section 611. As a result, the second printed circuit board section 610 may be arranged in the receptacle 631 of the laser diode holder 660 by bending through the recess 632. Preferably, the photodiode holder 622 is fastened to the laser diode holder 660, preferably to the receptacle 631 of the laser diode holder 660. By the bending, the second printed circuit board section 610 is arranged approximately perpendicular to the first printed circuit board section 611, such that the photodiode 260 is arranged substantially perpendicular to a radiation direction 601 of a laser beam 253 of FIG. 2 and FIG. 5 of the laser diode 135, analogously to FIG. 5.

The collimation lens 230 is preferably arranged and fastened in the inner receptacle 643 of the laser module housing 210. The laser diode holder 660 having the printed circuit board 300, the laser diode 135, and the photodiode 260 is likewise arranged in the inner receptacle 643. For this purpose, the laser diode holder 660 is press-fitted into the inner receptacle 643 of the laser module housing 210, for example.

FIG. 7 shows the laser unit 130 of FIG. 6 in the assembled state. Here, the collimation lens 230 is preferably arranged, and preferably fixed, in an upper receiving section 711 of the inner receptacle 643 of the laser module housing 210. The receiving section 711 thereby forms the collimation-lens holder 220. The collimation lens 230 is preferably fixed in the inner receptacle 643 or the receiving section 711 by way of a material-bonded connection, in particular, an adhesive bond, and/or a press connection.

Furthermore, as described above, the cylindrical base body 635 of the laser diode holder 660 is arranged in the inner receptacle 643, in particular, in a lower receiving section 712. Preferably, a press connection is formed, at least in sections, between an outer circumference 713 of the cylindrical base body 635 and the receiving section 712. Alternatively, the cylindrical base body 635 may be fixed in the inner receptacle 643 or the receiving section 712 via a material-bonded connection.

Furthermore, the first printed circuit board section 611 of the flexible and foldable printed circuit board 300 is preferably fixed on the laser diode holder 660. Preferably, the first printed circuit board section 611 is fixed on the laser diode holder 660 by way of a material-bonded connection 1898. Preferably, the material-bonded connection 1898 is formed between an upper side 732 of the first printed circuit board section 611 of the flexible and foldable printed circuit board 300 facing the laser diode holder 660, and an underside 731 of the circumferential collar 637 of the laser diode holder 660 facing the first printed circuit board section 611.

Furthermore, the second printed circuit board section 610 of the flexible and foldable printed circuit board 300 is preferably fixed on the photodiode holder 622 by way of a material-bonded connection 1899. In particular, a side 735 of the second printed circuit board section 610 facing away from the photodiode 260 is fastened by way of the material-bonded connection 1899 to a side 736 of the photodiode holder 622 facing the second printed circuit board section 610. The photodiode holder 622 is preferably fixed in the inner receptacle 643, preferably in the lower receiving section 712 of the laser module housing 210, by way of an interference fit. According to one embodiment, at least one material-bonded connection 1898, 1899 is an adhesive bond.

Furthermore, FIG. 7 visualizes the laser diode holder 660 having the cylindrical base body 635, which comprises a receptacle 631 at its outer circumference. The receptacle 631 preferably comprises a recess 721 for arranging the photodiode 260 in the inner receptacle 636 of the laser diode holder 660. Preferably, the recess 721 is arranged perpendicular to the receptacle 631 within predefined tolerances.

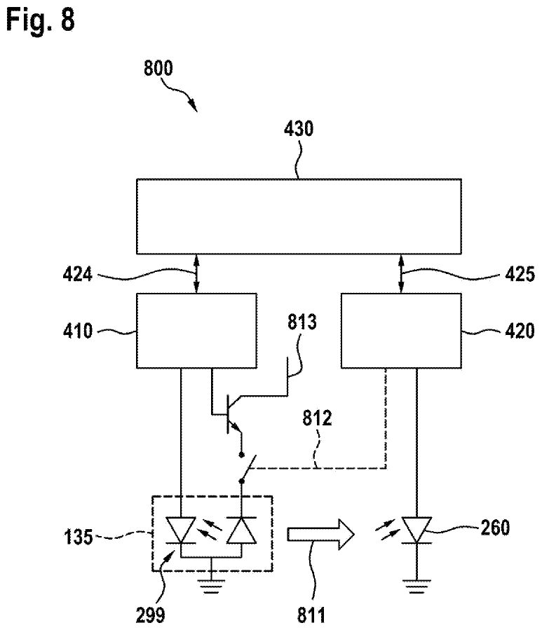

FIG. 8 shows an exemplary circuit 800 assigned to the laser unit 130 of FIG. 2 or FIG. 5 to FIG. 7. The circuit 800 comprises, by way of example, analogously to the circuit 400 of FIG. 4, the protection circuit 420 assigned to the photodiode 260, which is connected to further circuit parts 430 via the connection 425, as well as the automatic power control circuit 410 assigned to the laser diode 135, which is connected to the further circuit parts 430 via the connection 424. As described above, the further circuit parts 430 comprise, for example, a current/voltage supply and/or a control unit, in particular, the electronic unit 190 of FIG. 1 of the rotating laser 100 of FIG. 1.

The photodiode 260 is optically coupled to the laser diode 135 by scattered light 811 assigned to the laser diode 135. >Alternatively, optical coupling may occur via a beam splitter, for example, the beam splitter 270 of FIG. 2 or the outgoing side 272 of the beam splitter 270 of FIG. 2. The automatic power control circuit 410 measures the laser power by way of the photocurrent of the monitor diode 299 integrated into the laser diode 135 and controls the current supply to the laser diode 135. The protection circuit 420 measures the laser power by way of the photocurrent of the photodiode 260.

The protection circuit 420 is preferably configured to deactivate the laser diode 135 via a control line 812 by interrupting a current supply 813 assigned to the laser diode 135 to the laser diode 135 if the laser power measured by the photodiode 260 exceeds a predefined laser power limit value. Alternatively, the protection circuit 420 deactivates the automatic power control circuit 410 via an assigned control line, as described with reference to FIG. 4.

FIG. 9 shows the flexible and foldable printed circuit board 300 of FIG. 6 and FIG. 7 having the first printed circuit board section 611, on which the laser diode 135 is arranged, and having the second printed circuit board section 610 arranged perpendicular to the first printed circuit board section 611, having the photodiode 260 and the photodiode holder 622. Preferably, the laser diode 135 comprises a radiation characteristic 911 having a divergence, that is to say a widening of the laser beam 253 over a certain distance, which comprises an elliptical cross section 920. The divergence of the laser beam 253 emitted by the laser diode 135 is preferably formed perpendicular to an optical axis 912 of the laser beam 253.

Due to the elliptical cross section, the divergence preferably has a comparatively small value in a first direction 921, which extends perpendicular to the optical axis 912, and the divergence preferably has a comparatively large value in a second direction 922 arranged perpendicular to the optical axis 912 and perpendicular to the first direction 921. In order to achieve coupling of the scattered light 811 into the photodiode 260 that is as good as possible, the photodiode 260 is therefore preferably positioned substantially or approximately along the direction 922 of greatest divergence relative to the laser diode 135.

With knowledge of the divergence of the laser diode 135, a suitable position of the photodiode 260 relative to the optical axis 912 of the laser beam 253 of the laser diode 135 in a radial direction 902 and an axial direction 903 may be ascertained, which enables a laser-power measurement by the protection circuit 420 with a sufficient signal-to-noise ratio while simultaneously excluding shading of the optical path between the laser diode 135 and the collimation lens 230 in FIG. 5 to FIG. 7 by the photodiode 260.

FIG. 10 shows the arrangement of the photodiode 260 relative to the laser diode 135 as viewed in the direction of an arrow 901 of FIG. 9, for illustrating the radiation characteristic 911 of the laser diode 135. This illustrates the elliptical cross section 920, as well as the first direction 921 preferably assigned to the smallest divergence and the second direction 922 preferably assigned to the greatest divergence. As described above, the photodiode 260 is preferably arranged substantially/approximately in the direction 922 of the greatest divergence.

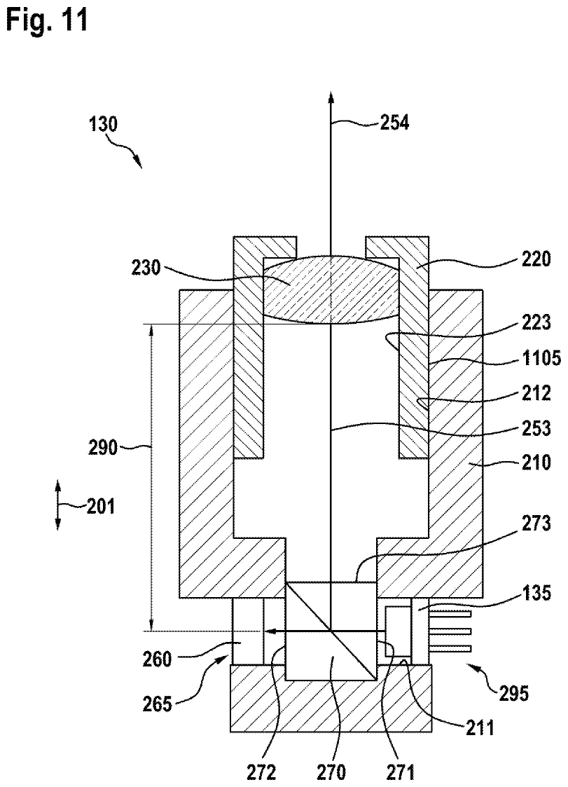

FIG. 11 shows the laser unit 130 of FIG. 2 having an alternative embodiment of the collimation-lens holder 220. The collimation-lens holder 220 preferably comprises merely the lens receptacle 223, in which the collimation lens 230 is arranged. An outer circumference 1105 of the collimation-lens holder 220 is preferably arranged in the inner receptacle 212 of the laser module housing 210. The collimation-lens holder 220 is arranged so as to be displaceable in the inner receptacle 212 of the laser module housing 210 along the longitudinal extent 201 of the laser module housing 210 for setting the spacing 290 between the laser diode 135 and the collimation lens 230 in the inner receptacle 212.

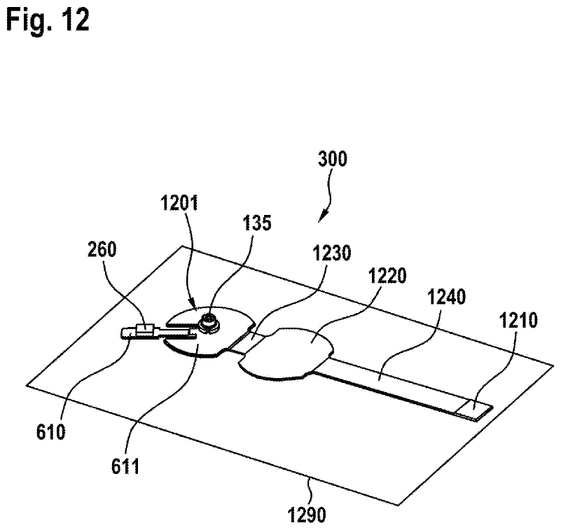

FIG. 12 shows the flexible and foldable printed circuit board 300 of FIG. 3 in the unfolded state having the first printed circuit board section 611, on which the laser diode 135 is arranged, and the second printed circuit board section 610 having the photodiode 260, as viewed from an upper side 1201 of the printed circuit board 300. The second printed circuit board section 610 is arranged in a common plane 1290 with the first printed circuit board section 611.

A third printed circuit board section 1220 that is arrangeable parallel to the first printed circuit board section 611 is provided. The third printed circuit board section 1220 is also arranged in the plane 1290. The third printed circuit board section 1220 is preferably connected to the first printed circuit board section 611 via a connecting section 1230.

Preferably, the first printed circuit board section 611 or the third printed circuit board section 1220 is connected to a contacting element 1210 via a flexible connecting section 1240. The third printed circuit board section 1220 is connected to the contacting element 1210 via the flexible connecting section 1240. The contacting element 1210 is preferably formed merely on the upper side 1201 of the printed circuit board 300.

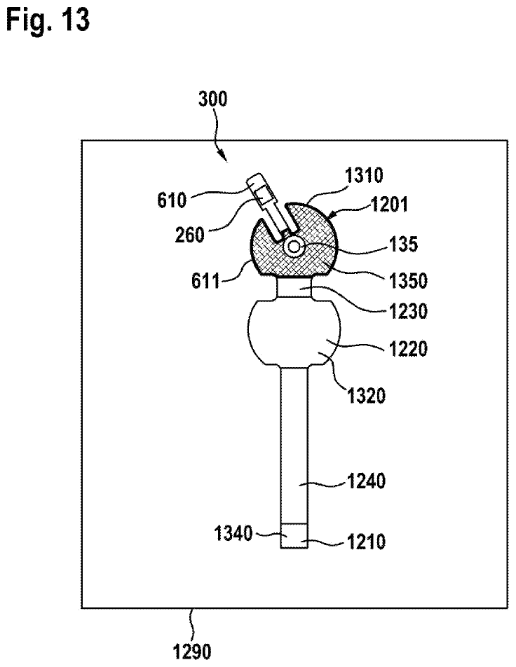

FIG. 13 shows the flexible and foldable printed circuit board 300 of FIG. 12 in the plane 1290 as viewed from the upper side 1201. Preferably, the first printed circuit board section 611, the third printed circuit board section 1220 and/or the contacting element 1210 comprise reinforcing elements 1310, 1320, 1340. A reinforcing element 1310 is assigned to the first printed circuit board section 611, a reinforcing element 1320 is assigned to the third printed circuit board section 1220, and a reinforcing element 1340 is assigned to the contacting element 1210.

By way of example, a fixing element 1350 for forming the material-bonded connection 1898 with the laser diode holder 660 of FIG. 6 and FIG. 7 is assigned, at least in sections, to the first printed circuit board section 611. Preferably, the fixing element 1350 is a double-sided adhesive tape.

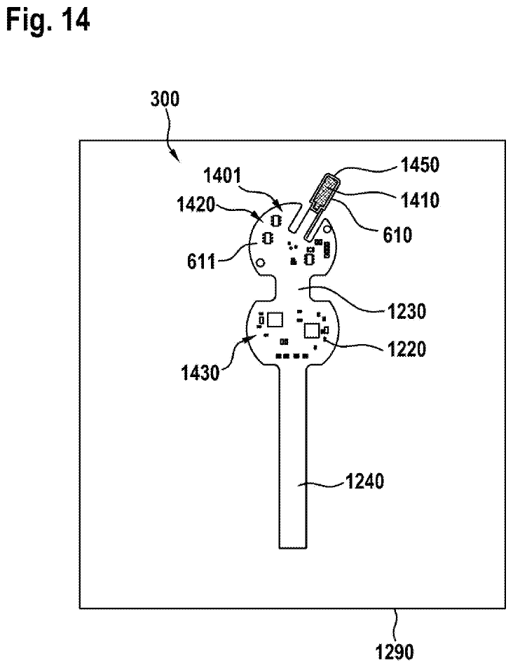

FIG. 14 shows the flexible and foldable printed circuit board 300 of FIG. 12 and FIG. 13 in the plane 1290 as viewed from an underside 1401 opposite the upper side 1201 of FIG. 12 and FIG. 13. The first printed circuit board section 611 and/or the third printed circuit board section 1220 preferably comprise electrical components 1420, 1430 on the underside 1401. The electrical components 1420 are assigned to the first printed circuit board section 611, and the electrical components 1430 are assigned to the third printed circuit board section 1220.

Preferably, a reinforcing element 1450 is assigned to the second printed circuit board section 610. Preferably, a fixing element 1410 for forming the material-bonded connection 1899 with the photodiode holder 622 of FIG. 6 and FIG. 7 is assigned, at least in sections, to the second printed circuit board section 610. Preferably, the fixing element 1410 is a double-sided adhesive tape.

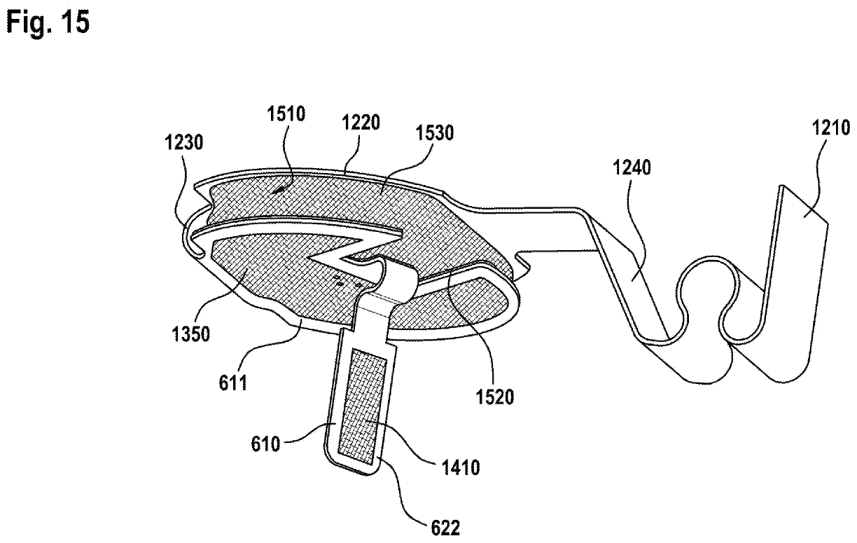

FIG. 15 shows the flexible and foldable printed circuit board 300 of FIG. 12 to FIG. 14 in the folded state, in which the second printed circuit board section 610 is arranged at least approximately perpendicular to the first printed circuit board section 611, and the third printed circuit board section 1220 is arranged at least approximately parallel to the first printed circuit board section 611. Furthermore, the flexible connecting section 1240 is folded. In this case, FIG. 15 illustrates the fixing element 1350 assigned to the first printed circuit board section 611 and the fixing element 1410 assigned to the second printed circuit board section 610.

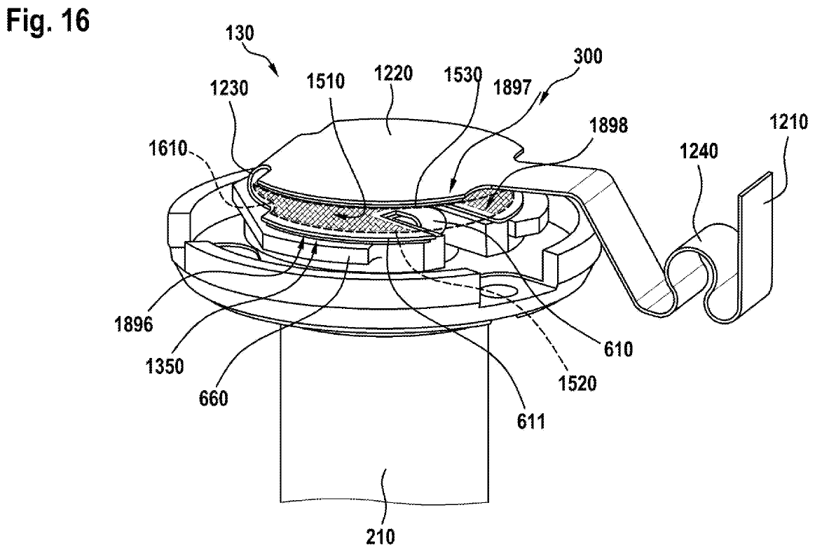

Preferably, the first and third printed circuit board sections 611, 1220 form a receptacle 1510. The receptacle 1510 is preferably formed in the manner of a sandwich. A spacer element (1610 in FIG. 16) is preferably arrangeable in the receptacle 1510, By way of example, a fixing element 1520, 1530 for forming a material-bonded connection (1896, 1897 in FIG. 16) is assigned, at least in sections, to the first and/or third printed circuit board section 611, 1220.

FIG. 16 shows the laser unit 130 of FIG. 6 and FIG. 7 having the flexible and foldable printed circuit board 300 of FIG. 12 to FIG. 15. A spacer element 1610 is arranged in the receptacle 1510 formed between the first and third printed circuit board sections 611, 1220. By way of the spacer element 1610, in particular, by way of a sufficient thickness of the spacer element 1610, control of a bending radius of the connecting section 1230 of the printed circuit board 300 may be achieved. Furthermore, the spacer element 1610 serves as electrical insulation in order to prevent a short circuit between the first and third printed circuit board sections 611, 1220. The components 1420, 1430 arranged on the first and/or third printed circuit board section 611, 1220 are also mechanically protected.

The spacer element 1610 is preferably fixed on the first printed circuit board section 611 and/or on the third printed circuit board section 1220 by way of a material-bonded connection 1897, 1896. Preferably, the material-bonded connections 1897, 1896 are adhesive bonds, wherein the fixing element 1520 assigned to the first printed circuit board section 611 and/or the fixing element 1530 assigned to the third printed circuit board section 1220 together with the spacer element 1610 form the respective adhesive bond 1896, 1897. Preferably, the spacer element 1610 comprises a non-electrically conductive material.

Preferably, the spacer element 1610 comprises a soft material. By way of example, the spacer element 1610 comprises foam, rubber or felt. Alternatively, the spacer element 1610 is an injection-molded part.

Furthermore, FIG. 16 illustrates the material-bonded connection 1898 of the first printed circuit board section 611 to the laser diode holder 660 via the exemplary fixing element 1350.

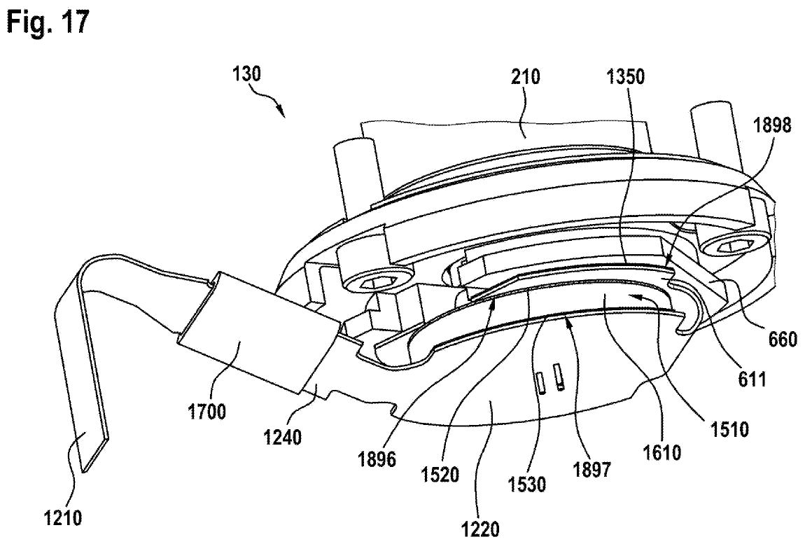

FIG. 17 shows the laser unit 130 of FIG. 16. A shielding element 1700 is assigned to the flexible and foldable printed circuit board 300. Preferably, the shielding element 1700 is fixed to the flexible and foldable printed circuit board 300 by way of a material-bonded connection, a latching connection, and/or a press connection. Preferably, the shielding element 1700 is arranged on the flexible connecting section 1240.

Preferably, the shielding element 1700 comprises ferrite. The shielding element 1700 is configured to improve the electromagnetic compatibility (EMC) of the laser unit 130.

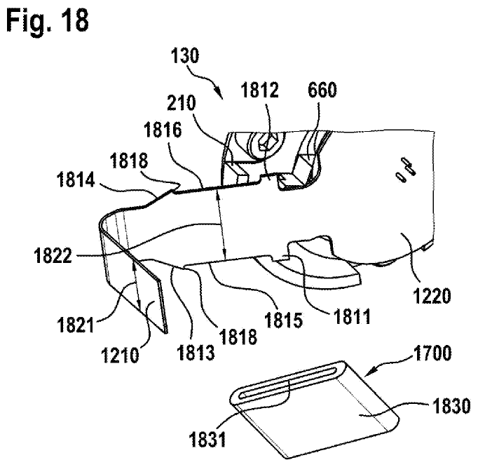

FIG. 18 shows the laser unit 130 of FIG. 17, wherein the shielding element 1700 is arranged next to the flexible connecting section 1240. Preferably, the flexible and foldable printed circuit board 300 comprises a receiving region 1815, 1816, which is preferably delimited by lateral webs 1811, 1812, 1813, 1814. By way of example, the shielding element 1700 comprises an inner receptacle 1831 for arrangement in the receiving region 1815, 1816 of the flexible and foldable printed circuit board 300.

The contact element 1210 has a width 1821 that widens, via at least one ramp-like web 1813, 1814, via two opposing ramp-like webs 1813, 1814, into a width 1822 of the receiving region 1815, 1816. The two ramp-like webs 1813, 1814 preferably form a latching function with retaining edges 1818. The retaining edges 1818 preferably prevent slipping of the shielding element 1700 from the receiving region 1815, 1816 of the printed circuit board 300.

Preferably, at least one web, the webs 1811, 1812, is formed in the manner of a projection and forms a stop function. Preferably, the webs 1811, 1812, 1813, 1814 have a width that is greater than the width 1822 formed between the receiving regions 1815, 1816. Alternatively or optionally, an interference fit is formed between the receiving region 1815, 1816 and the inner receptacle 1831 of the shielding element 1700 due to an oversize of the receiving region 1815, 1816.

The shielding element 1700 is preferably pushed onto the printed circuit board 300 in the region of the contact element 1210 in the course of assembly and arranged in the receiving region 1815, 1816 via the ramp-like webs 1813, 1814.

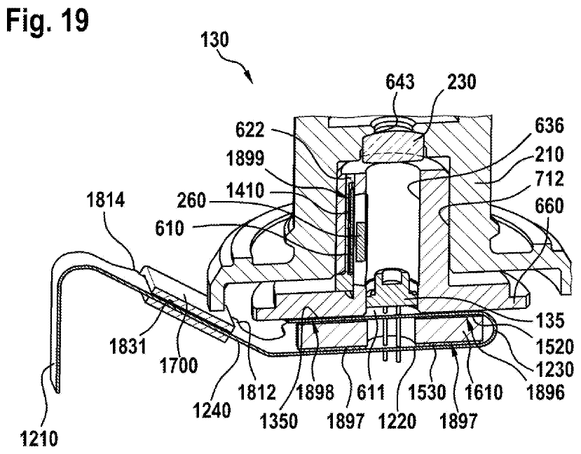

FIG. 19 shows the laser unit 130 of FIG. 17 and FIG. 18 having the shielding element 1700 on the flexible connecting section 1240 of the flexible and foldable printed circuit board 300. Furthermore, FIG. 19 illustrates the material-bonded connections 1896, 1897, 1898, 1899, which are formed, by way of example, in each case by way of fixing elements, in particular, adhesive elements 1520, 1530, 1350, 1410. Preferably, the fixing elements 1520, 1530, 1350, 1410 are formed as adhesive elements. It is noted that the material-bonded connections 1896, 1897, 1898, 1899 may also be formed as soldered connections or the like.

Alternatively, the flexible and foldable printed circuit board 300 or the first printed circuit board section 611 is fastened to the laser diode holder 660 by way of a soldered connection of the laser diode 135 press-fitted into the laser diode holder 660 to the first printed circuit board section 611.

What is claimed is:

1. A laser unit for a rotating laser, comprising:
a laser module housing;
a laser diode arranged in the laser module housing and configured to generate a laser beam;
a collimation lens arranged in the laser module housing and configured to collimate the laser beam; and
a flexible and foldable printed circuit board,
wherein the laser diode is arranged on the flexible and foldable printed circuit board.

2. The laser unit according to claim 1, wherein the flexible and foldable printed circuit board includes a first printed circuit board section, and a second printed circuit board section arranged perpendicular or parallel to the first printed circuit board section.

3. The laser unit according to claim 2, wherein the laser diode is arranged on the first printed circuit board section, and a photodiode is arranged on the second printed circuit board section.

4. The laser unit according to claim 1, further comprising a laser diode holder configured to arrange the laser diode in the laser module housing, wherein the laser diode holder is arranged in an inner receptacle of the laser module housing.

5. The laser unit according to claim 4, wherein the laser diode holder is arranged so as to be displaceable along a longitudinal extent of the laser module housing in the inner receptacle of the laser module housing.

6. The laser unit according to claim 4, wherein the flexible and foldable printed circuit board is arranged on the laser diode holder.

7. The laser unit according to claim 4, wherein a photodiode is provided, which is arranged in a photodiode holder, and the photodiode holder is arranged on the laser diode holder.

8. The laser unit according to claim 2, wherein the flexible and foldable printed circuit board further includes a third printed circuit board section arranged parallel to the first printed circuit board section.

9. The laser unit according to claim 8, wherein the first printed circuit board section or the third printed circuit board section is connected to a contacting element via a flexible connecting section.

10. The laser unit according to claim 8, wherein a receptacle is formed between the first and third printed circuit board sections, in which a spacer element is arranged.

11. The laser unit according to claim 8, wherein the first printed circuit board section is fixed to the laser diode holder by way of a first material-bonded connection, the second printed circuit board section is fixed to the photodiode holder by way of a second material-bonded connection, and/or the spacer element is fixed to the first printed circuit board section and/or the third printed circuit board section by way of a third material-bonded connection.

12. The laser unit according to claim 1, wherein a shielding element is assigned to the flexible and foldable printed circuit board.

13. The laser unit according to claim 12, wherein the flexible and foldable printed circuit board includes a receiving region, which is delimited by lateral webs, and the shielding element includes an inner receptacle configured for arrangement in the receiving region of the flexible and foldable printed circuit board.

14. The laser unit according to claim 12, wherein the shielding element is fixed to the flexible and foldable printed circuit board by way of a material-bonded connection, a latching connection, and/or a press connection.

15. A rotating laser comprising the laser unit according to claim 1.
